(19) United States
(12) Patent Application Publication
(10) Pub. No.: US 2007/0271780 A1
(43) Pub. Date: Nov. 29, 2007

(54) Method for producing a proximity switch and a proximity switch produced according to the method

(76) Inventors: Frederic Allemann, Courroux (CH); Norbert Schaffner, Bassecourt (CH); Pierre Andre Steullet, Delemont (CH)

Correspondence Address: ST. ONGE STEWARD JOHNSTON & REENS, LLC, 986 BEDFORD STREET, STAMFORD, CT, 06905-5619, US

(21) Appl. No.: 11/688,979

(22) Filed: Mar. 21, 2007

(30) Foreign Application Priority Data
Mar. 21, 2006 (DE) 102006012792.7-16

(51) Int. Cl. H05K 3/30

(52) U.S. Cl. 29/841

(57) ABSTRACT

The invention relates to a method for producing a proximity switch, in which the molding of the electronic components with a plastic compound results in a molded body whose external dimensions correspond to the internal dimensions of a housing and the molded part is inserted into the housing and connected with it. To reduce production tolerances it is proposed that, before the molding with the plastic compound, a sensor head and a switching plate are connected mechanically to one another, so that they can move with respect to one another, by means of essentially flexible electric lines, that these two parts are inserted into an injection casting form, that they are held or brought there by means of fixer elements in a firm, predetermined position to one another and to the wall of the injection casting form, and that they are molded in this fixed position.

### CROSS-REFERENCE TO RELATED APPLICATIONS

The present application claims priority of German Patent Application No. 10 2006 012792.7-16, filed on Mar. 21, 2006, the content of which is incorporated herein by reference.

### FIELD OF THE INVENTION

The invention relates to a method for producing a proximity switch, in which the molding of the electronic components with a plastic compound results in a molded body whose external dimensions correspond to the internal dimensions of a housing and the molded part is inserted into the housing and connected with it. In addition the invention relates to a proximity switch produced according to the method.

### BACKGROUND OF THE INVENTION

The prior art teaches, in DE 29724696 U1, a proximity switch, whose electronic components, with connecting elements remaining accessible, are at least primarily molded with plastic compound, while the plastic compound surrounding the electronic components forms a firm molded body. The firm molded body there can be at least partly inserted into a sleeve element and is manufactured, in a first working step, by molding of the electronic components with a plastic compound.

DE 10121776 teaches how to secure a carrier plate in a housing by injection of a plastic compound.

Also known in the art is how to fix the electronic components there by means of a casting compound filled in the sensor housing.

### SUMMARY OF THE INVENTION

All the aforementioned methods entail the problem of how to position the electronic components exactly with respect to one another, because even minor variations in the distance lead to different electronic characteristics of the proximity switches. Minor modifications in the distance position of the coil to the housing wall or to the plate lead, for instance in an inductive proximity switch, to major changes in the switching distance. It is therefore a major goal to conform to the minutest manufacturing tolerances.

It is therefore the object of the invention to indicate measures that can allow manufacturing tolerances to be reduced.

This object is fulfilled through the invention described in the claims, so that every claim constitutes an independent fulfillment of the object. Claim 1, first, essentially provides that, before the spray molding with plastic compound, a sensor head and a plate are connected to one another by essentially flexible conductors. The two electronic components, that is, the sensor head and the plate, can thereby be minutely displaced with respect to one another mechanically, but are connected to one another. These two parts are placed in an injection casting form. The injection casting form has fixer elements. These fixer elements can preferably be displaced and are configured as punches or pins. The two parts are held in, or brought into, a firm, predetermined position with respect to one another and to the wall of the injection casting form. This occurs, for instance, by moving the punch or pin out of the wall of the closed, or still open, injection casting form. In the process the two components are slightly displaced with respect to one another. In the fixed position they assume a position that can be reproduced. Thus a reproducible fine adjustment of the position of the individual components with respect to one another and to the wall of the injection casting form is possible. Then the injection casting compound is injected. During the filling of the injection casting compound, the fixer elements remain in their position securing the electronic compounds, so that the flowing or flowing pressure of the plastic injected into the form cannot lead to a shift in position of the electronic components. Each molded body produced in this manner thus possesses electronic components that lie exactly, with the minimal manufacturing tolerances, o the same spot with respect to one another and to the wall of the molded form. Consequently the electronic components lie in the same position to the housing wall, which can consist of metal, even after insertion of the form part in the sensor housing. If the proximity switch is an inductive proximity switch, then it can also be installed flush, because with most of the flush, inductive proximity switches in which a plate and one or more coils are located in a metal housing, the position of the coils to the housing and insulation is highly critical with respect to the switching behavior of the switch. The position becomes all the more critical the small the switch becomes. The method, however, is suited not just to the manufacture of inductive proximity switches but also to the manufacture of capacitive proximity switches. The fixer elements, which can be in the form of punches or pins that can move out of the wall of the injection casting form, contain not only the sensor head, which can be a coil carrier, and the plate in a fixed position, but can also if necessary contain a protective ring or a protective sleeve. The coil carrier can consist of plastic or ferrite. In the latter case it constitutes a coil core. The fixer elements can be replaced after the molding. It is possible then to mold this body form produced in this way with a second injection casting compound. The first injection casting compound can be a transparent plastic, so that light diodes that are positioned on the plate are visible from the outside looking in. This first, transparent plastic body, after withdrawal of the punches, configures channels, which in a second molding step are filled up with a non-transparent plastic. The sensor front surface can also be injected with this non-transparent plastic, so that the front surface of the sensor, that is, the immediate sensor surface, is configured by the body form itself. The covering cap, which is otherwise required in proximity switches according to the state of the art, can be dispensed with. The blank produced in this manner can then be inserted into a tube-shaped housing. The tube can, for instance, be of metallic material. The free pay between the blank and the housing inner wall is then filled with a plastic compound. Here too the plastic can be inserted in an injection casting process. It is also possible to fill the housing with a casting compound.

In addition, the invention relates to a proximity switch that is produced according to this method and in which it is essential that the immediate front surface of the molded body forms the sensor surface. In this proximity switch the electronic components, that is, the coil carrier, the switching plate, and the protective sleeve, are distanced from one another. The coil carrier is connected with the switching plate only by cords. It is at a distance from the plate and from the protective sleeve that surrounds it. The protective sleeve also is at a distance from the switching plate and from the sensor housing wall.

An embodiment of the invention is described hereafter with reference to the appended illustrations.

### BRIEF DESCRIPTION OF THE DRAWINGS

FIG. 1 is FIG. 1 shows a longitudinal section through a sensor part situated on the head side.

FIG. 2 shows a section along the line II-II in FIG. 1.

FIG. 3 shows a section along the line III-III in FIG. 1.

FIG. 4 shows a second embodiment depicted as in FIG. 1.

### DETAILED DESCRIPTION OF THE INVENTION

The two proximity switches depicted in the embodiments are inductive proximity switches. They include a sensor housing 1, which is configured as a metallic tube. In the sensor housing 1 is a molded body 6, which at least partly surrounds a switching plate 4 and completely surrounds a coil carrier 2 and a protective sleeve 5 that surrounds the coil carrier 2 and, in some areas, the switching plate 4. The sensor housing 1 has the shape of a tube in the embodiments. When completely installed, the tube is completely filled with an injection casting compound or a different filling compound, which closely surrounds the plate.

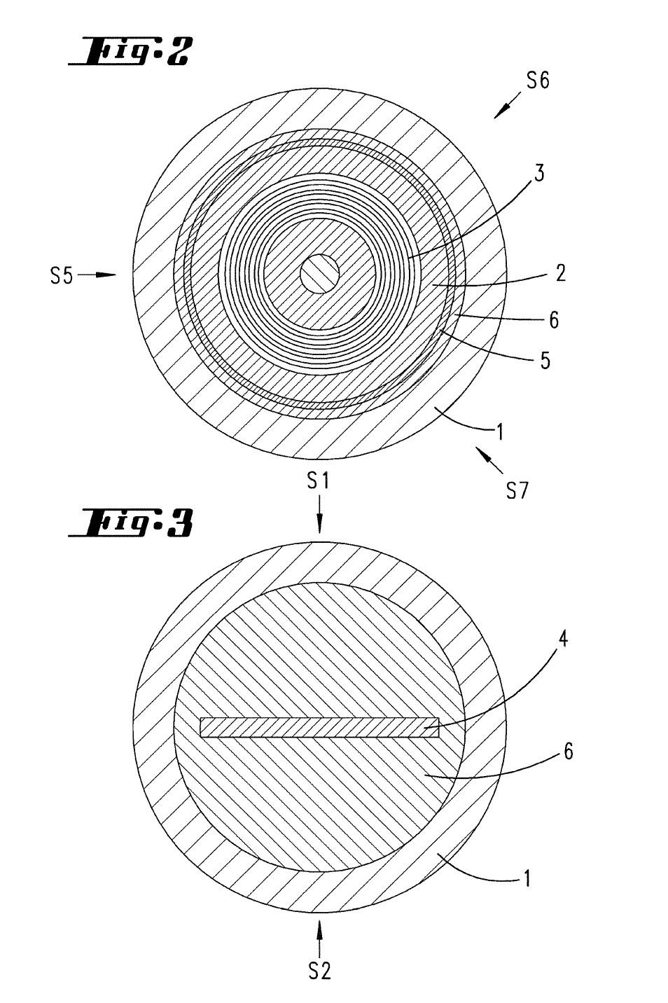

As can be seen from FIG. 2, the coil carrier 2 has a rotation-symmetrical structure, so that the rotation symmetry axis of the coil carrier 2 or of the protective sleeve 5 coincides with the axis of the sensor housing 1. The coil carrier 2 in this embodiment can consist of a ferrite material and can form a circular-shaped channel open toward the front end of the coil carrier 2, in which channel a sensor coil 3 is situated. The coil 3 is electrically connected with the switching plate 4 by means of flexible lines, for instance a connecting line 9, configured by a cord. A gap 10 is found between the coil carrier 2 and the switching plate 4. The coil carrier 2 is surrounded by the protective sleeve 5. A gap 2 is likewise found between the coil carrier 2 and the protective sleeve 5. The protective sleeve 5 also surrounds the head-end segment of the switching plate 4 at a distance 11.

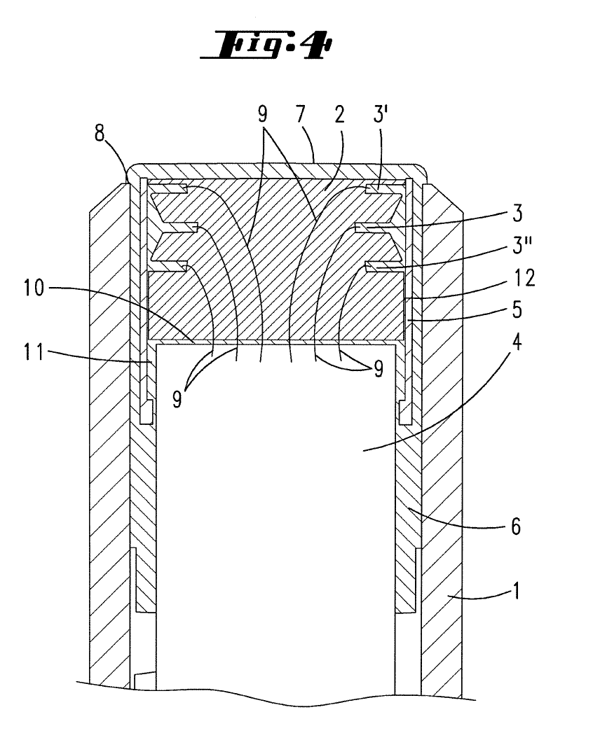

As can be seen from FIG. 3, the plate 4 lies in the center of the cavity of the sensor housing 1. The plate thus runs on a diametral line.

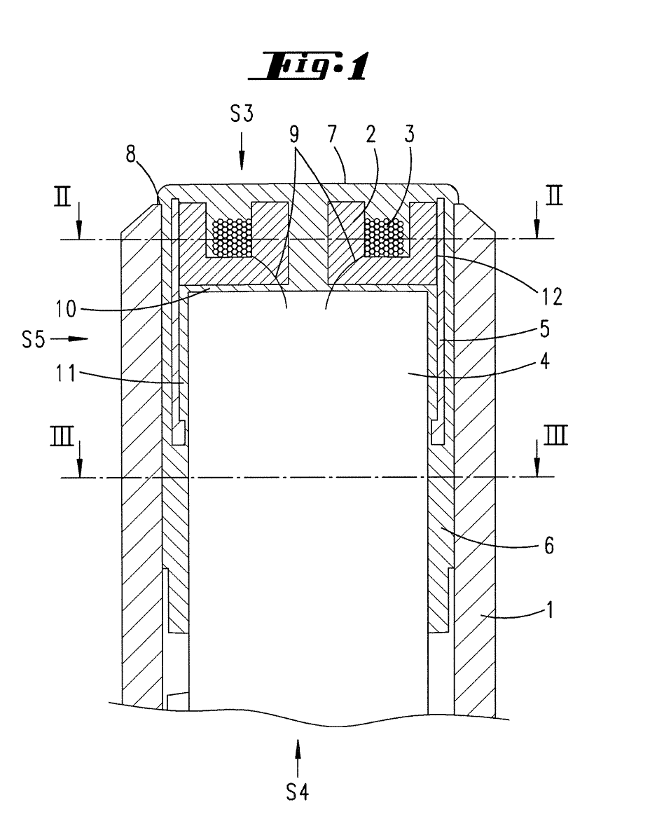

The embodiment of FIG. 4 is distinguished essentially only by the shape of the coil carrier 2 from the embodiment shown in FIG. 1. There the coil carrier 2 is made of plastic and altogether forms three peripheral grooves for the insertion of three coils 3, 3′, 3″, which each are connected with the plate 4 by means of flexible connecting lines 9, so that when not assembled, the coil carrier 2 and the switching plate 4 form a component set, so that the elements of this set are associated flexibly and movably to one another. The coil 3 can be a sender coil. The two coils 3′, 3″ are receiver coils, which are switched to one another in a differentiating circuit.

To produce the sensors described above, the coil carrier 2 and the switching plate 4 that is connected with the coil carrier 2 by the connecting lines 9 and the protective sleeve 5 are inserted into an injection mold. The previously described components, coil carrier 2, switching plate 4, and protective sleeve 5, can be moved with respect to one another and to the wall of the injection casting mold. To retain them in the injection casting mold at a distance to the wall of the injection casting mold and with a distance to the respective other electronic components, punches or pins, and in particular double punches or double pins, are provided, which can move out of the wall of the injection casting mold in order to bring the components 2, 4, 5 into position and to hold them in this position during the injection of the plastic.

These fixer elements, which preferably consist of punches, are shown schematically as arrows S1 to S7 in the illustrations. Thus arrows S1, S2 symbolize two punches or punch groups that can move toward one another and that hold the plate 4 in position. For securing the plate 4, still additional punches can be provided, which in particular define the axis position of the plate. Punches acting in axial direction are symbolized by arrows S3, S4. Arrows S5, S6, S7 symbolically depict punches that can fix the electronic components and in particular the plate 4 or protective ring 5 in the third spatial direction.

The coil carrier 2 is fixed, in the same manner, in the three spatial directions by punches S1, S7 that grip onto the coil carrier at an appropriate site. Here the coil carrier 2 assumes a fixed spatial position with respect to the wall of the injection casting form and the plate 4. The protective sleeve 5 also is fixed by appropriately shaped punches S1, S7 in a firm spatial position with respect to the switching plate 4, the coil carrier 2, and the wall of the injection casting form.

In mass production each of the aforementioned electronic components 2, 4, 5 is thus positioned exactly in the same position with the exception of minor tolerances.

The electronic components 2, 4, 5 positioned in this way are then at least partly molded with a plastic compound. To accomplish this, a plastic compound 6 is inserted into the injection casting form. While it is advantageous if the protective sleeve 5 and the coil carrier 2 are molded completely with a plastic compound 6, it is sufficient if the plate 4 is molded merely partly by the injection casting compound 6.

With the previously described process steps a first molded body is formed, which has channels after the withdrawal of the punches S1, S7. These channels are filled up by a second injection casting compound in a second injection casting step. This injection casting compound can be a non-transparent injection casting compound. The first injection casting compound can be transparent, so that light diodes positioned on the plate are visible from outside. The areas of the transparent body that was first produced, through which the light diodes are intended to shine, are not molded by the non-transparent injection casting compound.

The front surface of the molded body 6 formed by the molding constitutes the immediate sensor surface 7 behind which the coil carrier 2 is located. This sensor surface 7 is preferably configured by the plastic compound of the last molded plastic, so that it is not transparent. An additional cap covering of the front side of the molded body has thereby become dispensable.

As can be seen from the illustrations, the gap intervals 10, 11, 12 between the coil carrier 2, switching plate 4, and protective sleeve 5, as well as the area surrounding the protective sleeve 5, are completely filled with plastic. The individual electronic components 2, 4, 5 are thus at a mutual distance from one another in the molded body formed by the injection casting compound 6.

In the area of the sensor surface 7, the molded body 6 forms a peripheral stage, with which the molded boy is contiguous on a ring-shaped front side of the sensor housing 1. This produces also an axial localization of the molded body 6 inside the sensor housing 1. If the outer diameter of the molded body 6 corresponds essentially exactly to the inner diameter of the circular cylindrical sensor housing 1, the installation can consist merely of inserting the molded body 6 into the sensor housing 1. The molded body can be held there with appropriate fixer agents, for instance a headless pin, or with cement.

If the blank produced with the described process steps does not completely fill up the cavity of the tube-shaped sensor housing 1, then the latter can be filled with a casting compound after installation of the blank.

All described characteristics are (in themselves) essential to the invention. The publication of the application hereby also includes in its entirety the publication content of the related/appended priority documents (copy of the preliminary application), for the additional purpose of including characteristics of these documents in the claims of the present application.

1. A method for producing a proximity switch, in which the molding of the electronic components with a plastic compound results in a molded body whose external dimensions correspond to the internal dimensions of a housing and the molded part is inserted into the housing and connected with it, characterized in that, before the molding with the plastic compound, a sensor head and a switching plate are connected mechanically to one another, so that they can move with respect to one another, by means of essentially flexible electric lines, that these two parts are inserted into an injection casting form, that they are held or brought there by means of fixer elements in a firm, predetermined position to one another and to the wall of the injection casting form, and that they are molded in this fixed position.

2. A method according to claim 1, characterized in that the fixer elements are punches that can be moved out of the wall of the injection casting form and bring the sensor head, the plate, and possibly a protective ring or protective sleeve into the predetermined position or hold them there during the molding.

3. A method according to claim 1, characterized in that the proximity switch is an inductive proximity switch and the sensor head is a coil body that comprises at least one coil or is a coil core.

4. A method according to claim 1, characterized in that the fixer elements are moved back after the molding and the molded body is molded with a second injection casting compound.

5. A proximity switch produced by the method according to claim 1, characterized by an essentially cylindrical housing and an essentially cylindrical molded body that bears the electronic components, so that the immediate front surface of the molded body forms the sensor surface.

6. A proximity switch according to claim 5, characterized in that the electronic components are connected to one another by flexible wires, in particular cords.

7. A proximity switch according to claim 5, characterized in that the coil carrier and the protective sleeve are molded on all sides.

8. A proximity switch according to claim 6, characterized in that the coil carrier and the protective sleeve are molded on all sides.
